(19) United States
(12) Patent Application Publication
(10) Pub. No.: US 2024/0407195 A1
(43) Pub. Date: Dec. 5, 2024

(54) DISPLAY SUBSTRATE, MANUFACTURING METHOD THEREOF, AND DISPLAY DEVICE

(71) Applicants: CHENGDU BOE OPTOELECTRONICS TECHNOLOGY CO., LTD., Chengdu, Sichuan (CN); BOE TECHNOLOGY GROUP CO., LTD., Beijing (CN)

(72) Inventors: Ge Wang, Beijing (CN); Ming Hu, Beijing (CN); Zhiliang Jiang, Beijing (CN); Hong Chen, Beijing (CN); Yonglin Guo, Beijing (CN); Xiangnan Pan, Beijing (CN); Xiaomin Yuan, Beijing (CN); Chi Yu, Beijing (CN); Qingqing Yan, Beijing (CN); Qing He, Beijing (CN); Min Chen, Beijing (CN)

(73) Assignees: CHENGDU BOE OPTOELECTRONICS TECHNOLOGY CO., LTD., Chengdu, Sichuan (CN); BOE TECHNOLOGY GROUP CO., LTD., Beijing (CN)

(21) Appl. No.: 18/697,392

(22) PCT Filed: Aug. 9, 2023
(86) PCT No.: PCT/CN2023/111904

§ 371 Date: Mar. 29, 2024

(30) Foreign Application Priority Data
Aug. 31, 2022 (CN) 202211065002.X

(51) Int. Cl. H10K 59/121; H10K 59/12; H10K 59/126; H10K 59/131; H10K 77/10

(52) U.S. Cl. CPC H10K 59/1213; H10K 59/1201; H10K 59/126; H10K 59/131; H10K 77/111

(57) ABSTRACT

The present disclosure relates to a display substrate, a manufacturing method thereof, and a display device. The display substrate includes a flexible substrate, and a TFT driver circuit on the flexible substrate. The TFT driver circuit includes a patterned semiconductor layer on the flexible substrate. The display substrate further includes a shielding layer configured to shield fluoride ions from entering the flexible substrate. The shielding layer is arranged at a same layer as the semiconductor layer, and/or the shielding layer is located between the semiconductor layer and the flexible substrate.

### CROSS-REFERENCE TO RELATED APPLICATION

The present application claims priority to the Chinese patent application No. 202211065002.X filed in China on Aug. 31, 2022, a disclosure of which is incorporated herein by reference in its entirety.

### TECHNICAL FIELD

The present disclosure relates to the display product manufacture technical field, and in particular to a display substrate, a manufacturing method thereof, and a display device.

### BACKGROUND

Flexible OLED displays are gradually becoming the mainstream of mobile phone displays due to their excellent performance. The flexible OLED is typically made by fabricating a flexible PI (polyimide) substrate on glass. Then TFT driving circuits are made on the flexible PI substrate. Then EL light-emitting materials are vapor-deposited on the TFT driving circuit. After the vapor deposition is complete, TFE (thin film encapsulation) is used to encapsulate the light-emitting materials.

OLED displays using flexible PI substrates exhibit significantly worse image sticking compared to OLED displays using rigid glass substrates. The main reason is that impurities in the PI substrate affect the TFT driving circuits above the PI substrate, leading to a shift in TFT characteristics and resulting in image sticking.

The impurities in the PI substrate that affect image sticking are mainly fluorine ions. Fluorine ions can be removed from the PI raw materials to reduce the impact of the raw materials. However, during the flexible OLED manufacturing process, several steps introduce fluorine ions into the PI substrate, leading to contamination with fluorine ions. The most critical process is the semiconductor ion doping, where BF₃ is mostly used to dope boron ions into the semiconductor layer. In areas without shielding by semiconductor layer or a metal layer, high-energy ions can penetrate the film layer and enter the PI substrate. Due to the small size and strong binding force of fluorine ions, fluorine ions easily adhere to the PI substrate and cannot be expelled. When the TFT driving circuits above the PI substrate start to operate, the fluorine ions in the PI substrate move directionally with the change of electrical signals, forming an induced electric field. This induced electric field interferes with the TFT channel signals, causing the signal response to slow down and leading to display image sticking.

### SUMMARY

In order to solve the foregoing technical problems, the present disclosure provides a display substrate, a manufacturing method thereof, and a display device, solving the problem of displaying image sticking caused by fluorine ion contamination of the PI substrate.

In order to achieve the foregoing objective, the present disclosure provides the following technical solutions:

A display substrate, including a flexible substrate, and a TFT driver circuit on the flexible substrate, the TFT driver circuit including a patterned semiconductor layer on the flexible substrate, where the display substrate further includes a shielding layer configured to shield fluoride ions from entering the flexible substrate, the shielding layer is arranged at a same layer as the semiconductor layer, and/or the shielding layer is located between the semiconductor layer and the flexible substrate.

Optionally, the shielding layer is made of polysilicon material.

Optionally, the shielding layer is arranged at a same layer as the semiconductor layer, the shielding layer includes a hollowed-out portion and a shielding portion, and an orthogonal projection of the semiconductor layer on the flexible substrate is located within an orthogonal projection of the hollowed-out portion on the flexible substrate.

Optionally, the TFT driving circuit further includes a gate metal layer located on a side of the semiconductor layer away from the flexible substrate, an orthogonal projection of the semiconductor layer on the flexible substrate is a first projection, an orthogonal projection of the gate metal layer on the flexible substrate is a second projection, and the first projection and the second projection partially overlap to form a third projection;
the shielding layer is arranged at a same layer as the semiconductor layer, the shielding layer includes a hollowed-out portion and a shielding portion, and the third projection is located within an orthogonal projection of the hollowed-out portion on the flexible substrate.

Optionally, an orthogonal projection of the TFT driving circuit on the flexible substrate is a fourth projection, the shielding layer is arranged at a same layer as the semiconductor layer, the shielding layer includes a hollowed-out portion and a shielding portion, and the fourth projection is located within an orthogonal projection of the hollowed-out portion on the flexible substrate.

Optionally, the shielding layer is located between the semiconductor layer and the flexible substrate, and the shielding layer is made of polysilicon or metal.

Optionally, a buffer layer is arranged between the semiconductor layer and the flexible substrate, and the shielding layer is located between the buffer layer and the flexible substrate.

Optionally, a barrier layer and a buffer layer are sequentially arranged on the flexible substrate in a direction away from the flexible substrate, the semiconductor layer is formed on a side of the buffer layer away from the barrier layer, the shielding layer is arranged between the buffer layer and the barrier layer, or the shielding layer is arranged between the flexible substrate and the barrier layer.

An embodiment of the present disclosure further provides a method for manufacturing a display substrate, used for manufacturing the foregoing display substrate, including:
forming a polysilicon layer on the flexible substrate;
forming the patterned semiconductor layer and the shielding layer by performing a patterning process on the polysilicon layer.

An embodiment of the present disclosure further provides a method for manufacturing a display substrate, used for manufacturing the foregoing display substrate, including:
forming the shielding layer on the flexible substrate;
forming the buffer layer on the shielding layer;
forming a polysilicon layer on the shielding layer;
forming the patterned semiconductor layer by performing a patterning process on the polysilicon layer, or forming the patterned semiconductor layer and the shielding layer simultaneously by performing a patterning process on the polysilicon layer.

Optionally, before the forming the buffer layer on the shielding layer, the method further includes:
forming the barrier layer on the shielding layer.

An embodiment of the present disclosure further provides a method for manufacturing a display substrate, used for manufacturing the foregoing display substrate, including:
forming the barrier layer, the shielding layer and the buffer layer on the flexible substrate sequentially;
forming a polysilicon layer on the buffer layer;
forming the patterned semiconductor layer by performing a patterning process on the polysilicon layer, or forming the patterned semiconductor layer and the shielding layer simultaneously by performing a patterning process on the polysilicon layer.

An embodiment of the present disclosure further provides a display device, including the foregoing display substrate.

The beneficial effects of the present disclosure include: preventing the penetration of fluorine ions into the flexible substrate through the arrangement of the shielding layer, thereby improving OLED image sticking issues.

### BRIEF DESCRIPTION OF THE DRAWINGS

FIG. 1 is a state schematic diagram of light doping in a semiconductor layer in related technologies;

FIG. 2 is a state schematic diagram of heavy doping in a semiconductor layer in related technologies;

FIG. 3 is a state schematic diagram of image sticking in related technologies;

FIG. 4 is a schematic structural diagram of a semiconductor layer;

FIG. 5 is a schematic structural diagram of a semiconductor layer and a gate metal layer;

FIG. 6 is a first schematic structural diagram of a shielding layer according to an embodiment of the present disclosure;

FIG. 7 is a second schematic structural diagram of a shielding layer according to an embodiment of the present disclosure;

FIG. 8 is a state schematic diagram of light doping according to an embodiment of the present disclosure;

FIG. 9 is a state schematic diagram of heavy doping according to an embodiment of the present disclosure;

FIG. 10 is a state schematic diagram without image sticking according to an embodiment of the present disclosure;

FIG. 11 is a third schematic structural diagram of a shielding layer according to an embodiment of the present disclosure;

FIG. 12 is a fourth schematic structural diagram of a shielding layer according to an embodiment of the present disclosure.

### DETAILED DESCRIPTION

In order to make objects, technical details and advantages of the embodiments of the disclosure apparent, the technical solutions of the embodiments will be described in a clearly and fully understandable way in connection with the drawings related to the embodiments of the disclosure. Apparently, the described embodiments are just a portion but not all of the embodiments of the disclosure. Based on the described embodiments herein, those skilled in the art can obtain other embodiment(s), which should be within the scope of the disclosure.

In the description of the embodiments of the disclosure, it should be noted that, the orientation or position relationship indicated by the terms “center”, “on”, “below”, “left”, “right”, “vertical”, “horizontal”, “inside” and “outside”, etc. is an orientation or position relationship based on what is shown in the drawings, it is only for the convenience of describing the disclosure and simplifying the description, but does not indicate or imply that the apparatus or element referred to must have a specific orientation, and be constructed and operated in a specific orientation, and therefore cannot be understood as limiting the disclosure. Furthermore, the terms “first”, “second”, “third”, etc. are used for descriptive purposes only and are not to be construed as indicating or implying relative importance.

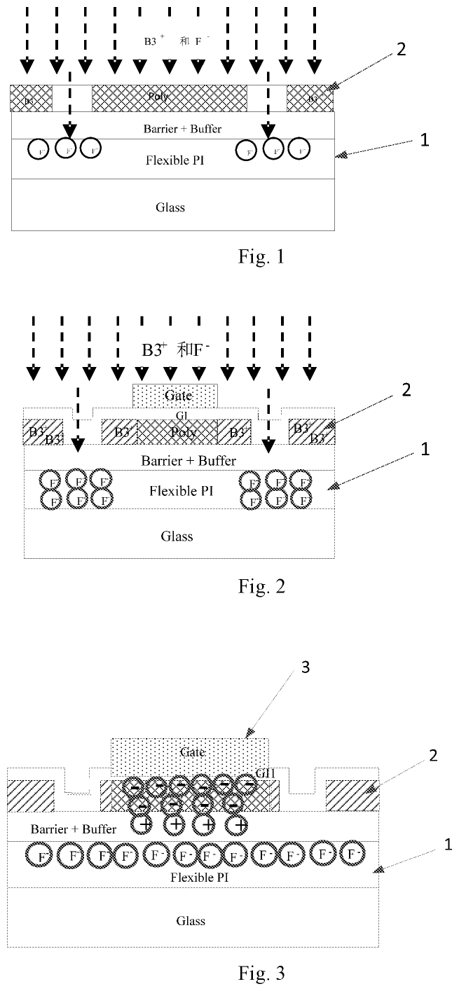

Referring to FIG. 1 and FIG. 2, the semiconductor ion doping process includes light doping and heavy doping, where BF₃ is mostly used to dope boron ions. In areas without shielding by polysilicon or a metal layer (refer to gate metal layer 3 in FIG. 2), high-energy ions can penetrate the film layer and enter the PI substrate. Due to the small size and strong binding force of fluorine ions, fluorine ions easily adhere to the PI substrate 1 and cannot be expelled. When the TFT driving circuits above the PI substrate 1 start to operate, the fluorine ions in the PI substrate move directionally with the change of electrical signals, forming an induced electric field. This induced electric field interferes with the TFT channel signals, causing the signal response to slow down and leading to display image sticking, as shown in FIG. 3.

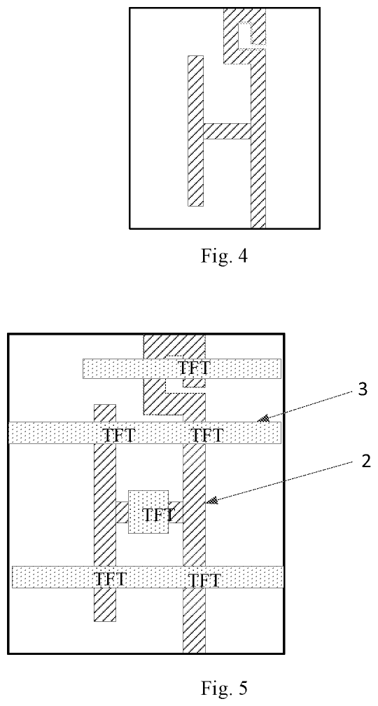

Referring to FIG. 4 to FIG. 12, in view of the foregoing problems, an embodiment of the present disclosure provides a display substrate, including a flexible substrate 1, and a TFT driver circuit on the flexible substrate 1, the TFT driver circuit includes a patterned semiconductor layer 2 on the flexible substrate 1, where the display substrate further includes a shielding layer 5 configured to shield fluoride ions from entering the flexible substrate 1, the shielding layer 5 is arranged at a same layer as the semiconductor layer 2, and/or the shielding layer 5 is located between the semiconductor layer 2 and the flexible substrate 1.

By arranging the shielding layer 5 to prevent the penetration of fluorine ions into the flexible substrate 1, the OLED image sticking issue is improved.

It should be noted that, the flexible substrate 1 is made of polyimide, but is not limited thereto.

In an exemplary embodiment, since the polysilicon film layer is denser and can resist the penetration of ion doping energy, the shielding layer 5 is made of polysilicon material, but is not limited thereto.

In an exemplary embodiment, the shielding layer 5 is arranged at a same layer as the semiconductor layer 2. The shielding layer 5 includes a hollowed-out portion and a shielding portion. The shape of the hollowed-out portion matches the shape of the semiconductor layer 2, allowing the semiconductor layer 2 to be located within the hollowed-out part (i.e., an orthogonal projection of the semiconductor layer 2 on the flexible substrate is located within an orthogonal projection of the hollowed-out portion on the flexible substrate).

The shielding layer 5 may be made of polysilicon. When the semiconductor layer 2 is also made of polysilicon, the shielding layer 5 and the semiconductor layer 2 can be formed by a synchronous photolithography process (i.e., patterning process, including exposure, development, etc.), reducing the number of process steps, but is not limited thereto.

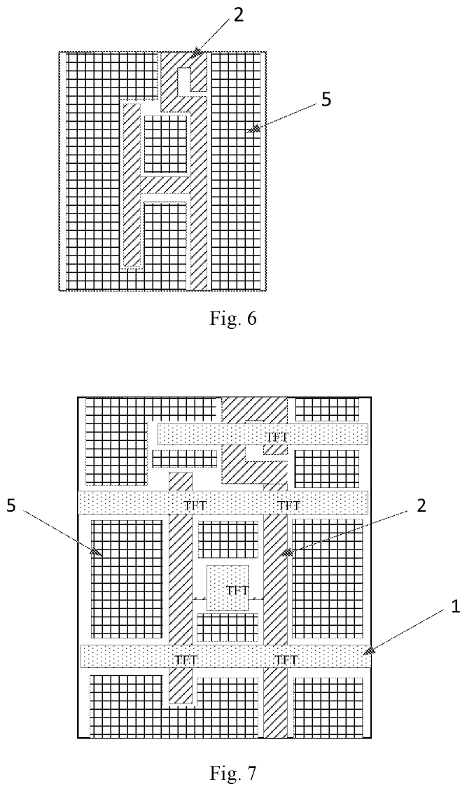

In the direction parallel to the flexible substrate 1, the shape of the semiconductor layer 2 is as shown in FIG. 4. The shape of the hollowed-out portion matches the shape of the semiconductor layer 2. The hollowed-out portion is arranged around the semiconductor layer 2 and serves as a shield, reducing or avoiding fluorine ions from entering the flexible substrate 1, as shown in FIG. 6.

Exemplarily, there is a gap between the shielding layer 5 and the semiconductor layer 2 to avoid affecting the performance of the TFT.

Exemplarily, the gap between the shielding layer 5 and the semiconductor layer 2 is greater than or equal to 1 um, but is not limited thereto.

In an exemplary embodiment, the shielding layer 5 is arranged at the same layer as the semiconductor layer 2. In the direction parallel to the flexible substrate 1, the shielding layer 5 surrounds the area around the shielding layer 5 and the gate metal layer 3 located on the semiconductor layer 2.

Referring to FIG. 5 and FIG. 7, the shielding layer 5 according to the present embodiment surrounds the area around the shielding layer 5 and the gate metal layer 3 located on the semiconductor layer 2, avoiding shielding the gate metal layer 3 to prevent affecting the performance of the TFT driving circuits.

The TFT driving circuit further includes a gate metal layer 3 located on a side of the semiconductor layer 2 away from the flexible substrate 1, an orthogonal projection of the semiconductor layer 2 on the flexible substrate 1 is a first projection, an orthogonal projection of the gate metal layer 3 on the flexible substrate 1 is a second projection, and the first projection and the second projection partially overlap to form a third projection;
the shielding layer 5 is arranged at a same layer as the semiconductor layer 2, the shielding layer 5 includes a hollowed-out portion and a shielding portion, and the shape of an orthogonal projection of the hollowed-out portion on the flexible substrate 1 matches the shape of the third projection, ensuring that the semiconductor layer 2 and the gate metal layer 3 are located within the hollowed-out portion (i.e., the third projection is located within the orthogonal projection of the hollowed-out part on the flexible substrate).

In an exemplary embodiment, an orthogonal projection of the TFT driving circuit on the flexible substrate 1 is a fourth projection, the shielding layer 5 is arranged at a same layer as the semiconductor layer 2, the shielding layer 5 includes a hollowed-out portion and a shielding portion, and the shape of an orthogonal projection of the hollowed-out portion on the flexible substrate 1 matches the shape of the fourth projection the fourth projection, ensuring that the entire TFT driving circuit is located within the hollowed-out portion (i.e., the fourth projection is located within the orthogonal projection of the hollowed-out part on the flexible substrate).

The TFT driving circuit includes the semiconductor layer 2, gate metal layer 3, source-drain metal layer, etc. In the present embodiment, the shielding layer 5 is arranged in areas where the TFT driving circuit is not arranged. This arrangement effectively prevents fluorine ions from entering the flexible substrate 1 while avoiding affecting the performance of the TFT driving circuit.

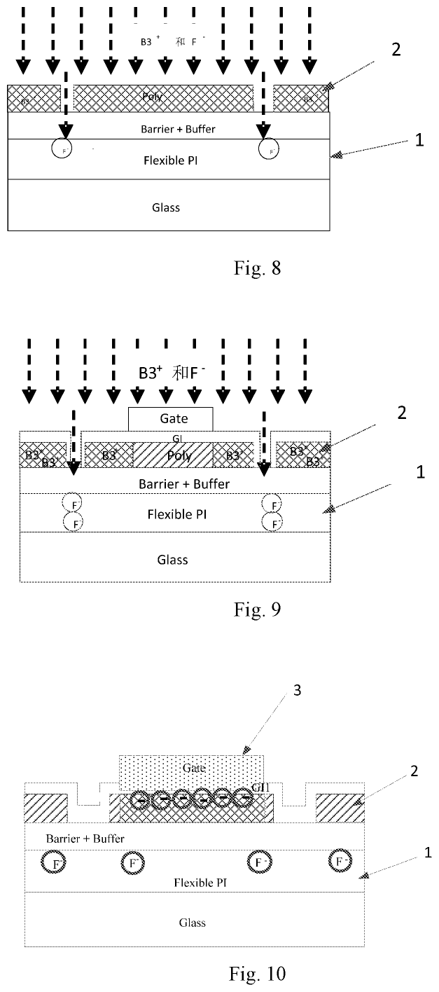

FIG. 8 is a state schematic diagram of light doping according to an embodiment of the present disclosure. FIG. 9 is a state schematic diagram of heavy doping according to an embodiment of the present disclosure. Comparing FIG. 1 with FIG. 8 and FIG. 2 with FIG. 9, through the arrangement of the shielding layer 5, whether performing the light doping process or the heavy doping process, the entry of fluorine ions into the flexible substrate 1 is reduced. Comparing FIG. 3 with FIG. 10, the addition of the shielding layer 5 significantly improves the issue of image sticking.

It should be noted that the shielding layer 5 is made of polysilicon and is arranged at the same layer as the semiconductor layer 2 made of polysilicon, which has the following advantages:
1. In the polysilicon-covered areas, fluorine ions cannot penetrate the polysilicon to enter the underlying flexible substrate 1 during the ion doping process. This can prevent the flexible substrate 1 from being contaminated by fluorine ions, avoiding the exacerbation of image sticking caused by fluorine ions.
2. The use of low-temperature polysilicon to shield non-circuit areas does not affect TFT performance and can save a step in shielding light exposure.
3. Polysilicon has translucency. The use of polysilicon to shield non-circuit areas has minimal impact on the display's transmittance.

It should be noted that in this embodiment, the TFT driving circuit may include only the driving transistors and switch transistors, or the TFT driving circuit may include the entire TFT driving circuit (not just including driving transistors and switch transistors, but also signal lines etc.).

In an exemplary embodiment, the shielding layer 5 is located between the semiconductor layer 2 and the flexible substrate 1, and the shielding layer 5 is made of polysilicon or metal.

The shielding layer 5 is located between the semiconductor layer 2 and the flexible substrate 1, that is, the shielding layer 5 is arranged at a different layer from the semiconductor layer 2. Therefore, the choice of materials for the shielding layer 5 allows for a broader selection compared to when the shielding layer 5 is arranged at the same layer as the semiconductor layer 2. Exemplarily, polysilicon or metals can be chosen, but are not limited to these, as long as fluorine ions can be prevented from entering the flexible substrate 1.

When the shielding layer 5 is arranged between the semiconductor layer 2 and the flexible substrate 1, an orthogonal projection of the shielding layer 5 on the flexible substrate 1 can fully cover the flexible substrate 1.

There are also other film layers between the flexible substrate 1 and the semiconductor layer 2. The placement of the shielding layer 5 can be determined as needed based on actual requirements.

Referring to FIG. 11, in an exemplary embodiment, a buffer layer 6 is arranged between the semiconductor layer 2 and the flexible substrate 1, and the shielding layer 5 is located between the buffer layer 6 and the flexible substrate 1.

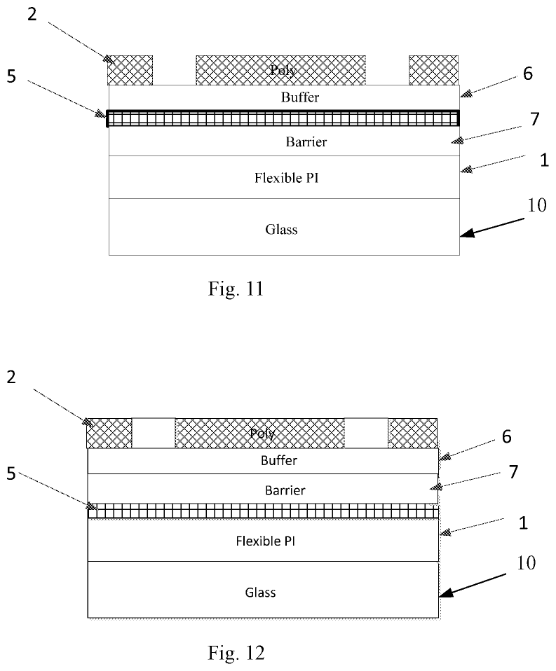

Referring to FIG. 12, in an exemplary embodiment, a barrier layer 7 and a buffer layer 6 are sequentially arranged on the flexible substrate 1 in a direction away from the flexible substrate 1, the semiconductor layer 2 is formed on a side of the buffer layer 6 away from the barrier layer 7, the shielding layer 5 is arranged between the buffer layer 6 and the barrier layer 7, or the shielding layer 5 is arranged between the flexible substrate 1 and the barrier layer 7.

The barrier layer 7 can reduce or prevent the infiltration of impurities, moisture, or external air from below the flexible substrate 1.

In the present embodiment, the flexible substrate 1 is formed on a glass base substrate 10.

An embodiment of the present disclosure further provides a method for manufacturing a display substrate, used for manufacturing the foregoing display substrate, including:
forming a polysilicon layer on the flexible substrate;
forming the patterned semiconductor layer and the shielding layer by performing a patterning process on the polysilicon layer.

An embodiment of the present disclosure further provides a method for manufacturing a display substrate, used for manufacturing the foregoing display substrate, including:
forming the shielding layer on the flexible substrate;
forming the buffer layer on the shielding layer;
forming a polysilicon layer on the shielding layer;
forming the patterned semiconductor layer by performing a patterning process on the polysilicon layer, or forming the patterned semiconductor layer and the shielding layer simultaneously by performing a patterning process on the polysilicon layer.

Optionally, before the forming the buffer layer on the shielding layer, the method further includes:
forming the barrier layer on the shielding layer.

An embodiment of the present disclosure further provides a method for manufacturing a display substrate, used for manufacturing the foregoing display substrate, including:
forming the barrier layer, the shielding layer and the buffer layer on the flexible substrate sequentially;
forming a polysilicon layer on the buffer layer;
forming the patterned semiconductor layer by performing a patterning process on the polysilicon layer, or forming the patterned semiconductor layer and the shielding layer simultaneously by performing a patterning process on the polysilicon layer.

An embodiment of the present disclosure further provides a display device, including the foregoing display substrate.

It is to be understood that the above embodiments are merely exemplary embodiments adopted to illustrate the principles of the present disclosure, but the present disclosure is not limited thereto. For those skilled in the art, various variations and improvements may be made without departing from the spirit and essence of the present disclosure, and these variations and improvements are also considered within the protection scope of the present disclosure.

1. A display substrate, comprising a flexible substrate, and a TFT driver circuit on the flexible substrate, the TFT driver circuit comprising a patterned semiconductor layer on the flexible substrate, wherein the display substrate further comprises a shielding layer configured to shield fluoride ions from entering the flexible substrate, the shielding layer is arranged at a same layer as the semiconductor layer, and/or the shielding layer is located between the semiconductor layer and the flexible substrate.

2. The display substrate according to claim 1, wherein the shielding layer is made of polysilicon material.

3. The display substrate according to claim 2, wherein the shielding layer is arranged at a same layer as the semiconductor layer, the shielding layer comprises a hollowed-out portion and a shielding portion, and an orthogonal projection of the semiconductor layer on the flexible substrate is located within an orthogonal projection of the hollowed-out portion on the flexible substrate.

4. The display substrate according to claim 2, wherein the TFT driving circuit further comprises a gate metal layer located on a side of the semiconductor layer away from the flexible substrate, an orthogonal projection of the semiconductor layer on the flexible substrate is a first projection, an orthogonal projection of the gate metal layer on the flexible substrate is a second projection, and the first projection and the second projection partially overlap to form a third projection;
the shielding layer is arranged at a same layer as the semiconductor layer, the shielding layer comprises a hollowed-out portion and a shielding portion, and the third projection is located within an orthogonal projection of the hollowed-out portion on the flexible substrate.

5. The display substrate according to claim 2, wherein an orthogonal projection of the TFT driving circuit on the flexible substrate is a fourth projection, the shielding layer is arranged at a same layer as the semiconductor layer, the shielding layer comprises a hollowed-out portion and a shielding portion, and the fourth projection is located within an orthogonal projection of the hollowed-out portion on the flexible substrate.

6. The display substrate according to claim 1, wherein the shielding layer is located between the semiconductor layer and the flexible substrate, and the shielding layer is made of polysilicon or metal.

7. The display substrate according to claim 1, wherein a buffer layer is arranged between the semiconductor layer and the flexible substrate, and the shielding layer is located between the buffer layer and the flexible substrate.

8. The display substrate according to claim 1, wherein a barrier layer and a buffer layer are sequentially arranged on the flexible substrate in a direction away from the flexible substrate, the semiconductor layer is formed on a side of the buffer layer away from the barrier layer, the shielding layer is arranged between the buffer layer and the barrier layer, or the shielding layer is arranged between the flexible substrate and the barrier layer.

9. A method for manufacturing a display substrate, used for manufacturing the display substrate according to claim 1, comprising:
forming a polysilicon layer on the flexible substrate;
forming the patterned semiconductor layer and the shielding layer by performing a patterning process on the polysilicon layer.

10. A method for manufacturing a display substrate, used for manufacturing the display substrate according to claim 1, comprising:
forming the shielding layer on the flexible substrate;
forming the buffer layer on the shielding layer;
forming a polysilicon layer on the shielding layer;
forming the patterned semiconductor layer by performing a patterning process on the polysilicon layer, or forming the patterned semiconductor layer and the shielding layer simultaneously by performing a patterning process on the polysilicon layer.

11. The method for manufacturing a display substrate according to claim 10, wherein before the forming the buffer layer on the shielding layer, the method further comprises:
forming the barrier layer on the shielding layer.

12. A method for manufacturing a display substrate, used for manufacturing the display substrate according to claim 1, comprising:
forming the barrier layer, the shielding layer and the buffer layer on the flexible substrate sequentially;
forming a polysilicon layer on the buffer layer;
forming the patterned semiconductor layer by performing a patterning process on the polysilicon layer, or forming the patterned semiconductor layer and the shielding layer simultaneously by performing a patterning process on the polysilicon layer.

13. A display device, comprising the display substrate according to claim 1.
